(19) United States
(12) Patent Application Publication
(10) Pub. No.: US 2026/0117382 A1
(43) Pub. Date: Apr. 30, 2026

(54) ADJUSTABLE PEDESTAL

(71) Applicant: LAM RESEARCH CORPORATION, Fremont, CA (US)

(72) Inventors: Gary B. LIND, Penn Valley, CA (US); Leonard KHO, San Francisco, CA (US); Andrew Paul EIB, Campbell, CA (US); Vinayakaraddy GULABAL, Yadgir (IN)

(21) Appl. No.: 19/117,197

(22) PCT Filed: Sep. 27, 2023
(86) PCT No.: PCT/US2023/033791

§ 371 Date: Mar. 31, 2025

Related U.S. Application Data
(60) Provisional application No. 63/413,837, filed on Oct. 6, 2022.

(51) Int. Cl. C23C 16/458; C23C 16/44; C23C 16/455; C23C 16/54

(52) U.S. Cl. CPC C23C 16/4585; C23C 16/4408; C23C 16/45565; C23C 16/54

(57) ABSTRACT

A pedestal assembly for a substrate processing system configured to perform bulk deposition on a substrate is configured to be raised and lowered. The pedestal assembly includes a stem portion, a baseplate portion disposed on the stem portion, and a pumping ring assembly. The baseplate portion is configured to support the substrate. The pumping ring assembly is disposed around the baseplate portion and includes a lower pumping ring and an upper pumping ring disposed above the lower pumping ring. The pumping ring assembly is configured to define an annular volume radially outside of the pumping ring assembly such that the pumping ring assembly separates the annular volume from a volume defined below the baseplate portion of the pedestal assembly.

### CROSS-REFERENCE TO RELATED APPLICATIONS

This application claims the benefit of U.S. Provisional Application No. 63/413,837, filed on Oct. 6, 2022. The entire disclosure of the application referenced above is incorporated herein by reference.

### FIELD

The present disclosure relates to pedestal designs for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically comprises a plurality of stations in which to perform deposition, etching, and other treatments on substrates such as semiconductor wafers. Examples of processes that may be performed on a substrate comprise a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, the substrate is disposed in the processing chamber on a substrate support such as an electrostatic chuck (ESC) or a pedestal. Process gases are introduced and, in some examples, plasma is struck in the processing chamber. The process gases are introduced using a gas distribution device, such as a showerhead.

### SUMMARY

A pedestal assembly for a substrate processing system configured to perform bulk deposition on a substrate is configured to be raised and lowered. The pedestal assembly includes a stem portion, a baseplate portion disposed on the stem portion, and a pumping ring assembly. The baseplate portion is configured to support the substrate. The pumping ring assembly is disposed around the baseplate portion and includes a lower pumping ring and an upper pumping ring disposed above the lower pumping ring. The pumping ring assembly is configured to define an annular volume radially outside of the pumping ring assembly such that the pumping ring assembly separates the annular volume from a volume defined below the baseplate portion of the pedestal assembly.

In other features, the pedestal assembly further includes a cover ring configured to be supported on the baseplate portion when the pedestal assembly is in a raised position, the cover ring including an inner edge configured to overlap and extend above an outer edge of the substrate when the substrate is arranged on the baseplate portion. The upper pumping ring is configured to support the cover ring when the pedestal assembly is in a lowered position. The upper pumping ring includes a ledge extending radially inward, and wherein the cover ring is supported on the ledge. The upper pumping ring includes an inner annular recess defined in the ledge, and wherein the cover ring is supported in the inner annular recess.

In other features, the pedestal assembly further includes a backside purge volume defined between the baseplate portion and the cover ring below the outer edge of the substrate and the inner edge of the cover ring. The pedestal assembly further includes a plurality of holes defined in an upper surface of the baseplate portion within the backside purge volume. The plurality of holes is configured to supply purge gas to the backside purge volume. The pedestal assembly further includes a plurality of holes defined in the upper pumping ring. The plurality of holes is configured to allow reactants to flow from a deposition volume above the baseplate portion into the volume defined below the baseplate portion.

In other features, the pedestal assembly includes a gap defined between the upper pumping ring and the lower pumping ring. The gap is configured to allow reactants to flow radially outward from below the lower pumping ring into the annular volume radially outside of the lower pumping ring assembly. The lower pumping ring is generally “C”-shaped. The lower pumping ring includes an annular body portion and legs extending radially outward from upper and lower ends of the annular body portion.

In other features, a processing chamber assembly includes the pedestal assembly. The processing chamber assembly further includes a first section that defines the volume below the baseplate portion. The annular volume radially outside of the pumping ring assembly is defined between inner surfaces of the first section and outer surfaces of the lower pumping ring. The processing chamber assembly further includes a top plate disposed on the first section. The top plate defines a deposition volume above the baseplate portion. The lower pumping ring is mounted to a lower surface of the top plate.

A substrate support for a substrate processing system configured to perform bulk deposition on a substrate includes a baseplate portion and a pumping ring assembly. The baseplate portion is configured to support the substrate. The pumping ring assembly is disposed around the baseplate portion. The pumping ring assembly is configured to define an annular volume radially outside of the pumping ring assembly such that the pumping ring assembly separates the annular volume from a volume defined below the baseplate portion of the substrate support.

In other features, the pumping ring assembly includes a lower pumping ring and an upper pumping ring disposed above the lower pumping ring. The baseplate portion includes an outward step. The substrate support further includes a cover ring configured to be supported on the outward step. The substrate support is configured to be raised and lowered. The cover ring is configured to be supported on the outward step when the substrate support is in a raised position and supported on the upper pumping ring when the substrate support is in a lowered position. The upper pumping ring includes a plurality of holes configured to allow reactants to flow from a deposition volume above the baseplate portion into the volume defined below the baseplate portion. A gap defined between the lower pumping ring and the upper pumping ring is configured to allow reactants to flow from below the upper pumping ring into the annular volume radially outside of the pumping ring assembly.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system comprising an example cover ring according to the present disclosure;

FIG. 2 shows an example processing chamber, showerhead, and substrate support according to the present disclosure;

FIG. 3A shows a processing chamber assembly including a pedestal assembly according to the present disclosure;

FIG. 3B shows example pumping rings disposed around a pedestal assembly according to the present disclosure; and

FIG. 3C shows an example backside purge volume around a baseplate portion of a pedestal assembly according to the present disclosure.

In the drawings, reference numbers may be reused to identify similar and/or identical elements.

### DETAILED DESCRIPTION

A substrate processing tool comprises one or more process modules or chambers. For example, a multi-station module (e.g., a quad-station module (QSM)) comprises a plurality of stations in which to perform deposition, etching, and other treatments on substrates. Different processes may be performed in respective stations. Conversely, a single station module comprises only a single station.

In some examples, a nucleation process (e.g., an atomic layer deposition (ALD) nucleation step) is performed in a first station of a multi-station module while bulk fill/deposition steps are performed in other stations of the multi-station module. Optimal chamber dimensions and geometry and/or process parameters may differ for respective steps. For example, optimal chamber pressure and temperature for the nucleation step may be lower than optimal chamber pressure and temperature for bulk deposition steps. However, since the stations in a multi-station module share the same processing chamber, processing chamber conditions may not be optimal for either nucleation or bulk deposition steps.

A process module according to the present disclosure comprises components optimized for bulk deposition steps of an ALD process. For example, the process module is a single station module configured to perform bulk deposition steps separately from a nucleation step. The nucleation step may be performed in a different module or tool prior to being transferred to the process module. Accordingly, nucleation and bulk deposition steps can be performed in respective optimal process conditions. Although described with respect to bulk deposition, the principles of the present disclosure may also be applied to other types of deposition

The process module comprises a substrate support (e.g., a pedestal with one or more heating zones), a carrier or cover ring, and one or more pumping rings disposed around the pedestal. The one or more pumping rings may include a lower pumping ring and an upper pumping ring. The cover ring extends above and overlaps an outer edge of the substrate to reduce deposition on the outer edge of the substrate. For example, inert gas is supplied to a gap between the pedestal and the cover ring and around the outer edge of the substrate. An outer edge of the cover ring overhangs an inner edge of the upper pumping ring. Accordingly, when the pedestal is lowered for transfer of the substrate, the cover ring is supported on the upper pumping ring. Conversely, when the pedestal is raised, an outer edge of the pedestal supports the cover ring.

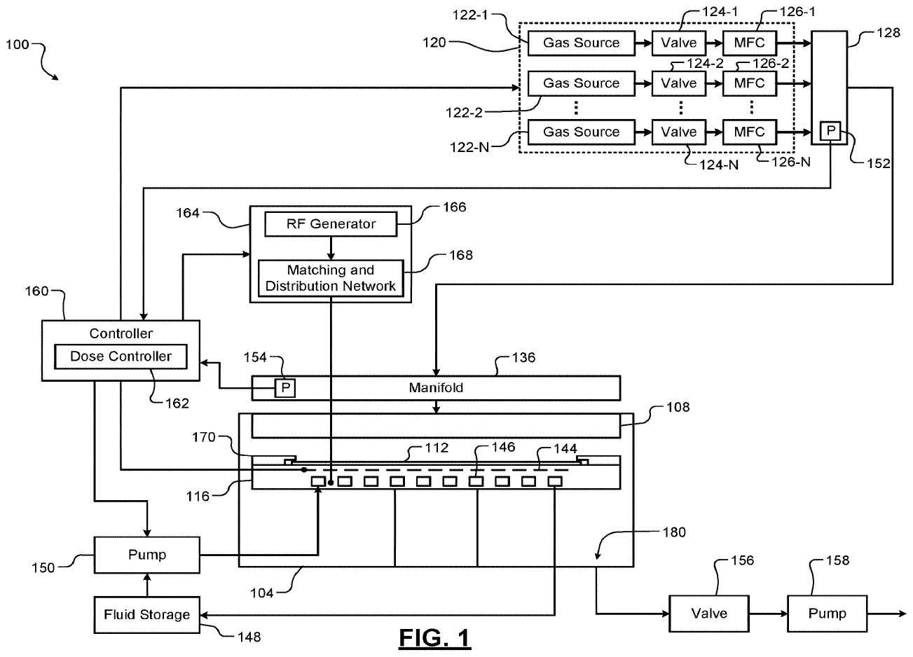

Referring now to FIG. 1, an example of a substrate processing system 100 comprising a processing chamber 104 according to the present disclosure is shown. The processing chamber 104 is comprised of an assembly of multiple sections or parts (e.g., separately machined processing chamber sections) as described below in more detail. The processing chamber 104 is configured to improve pumping uniformity during purging.

A showerhead 108 is arranged within an upper surface or portion of the processing chamber 104. A substrate 112 is arranged on a substrate support 116 (e.g., a pedestal configured for CVD and/or ALD deposition) during processing. For example, bulk deposition of an ALD process is performed on the substrate 112.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied to a manifold 136. An output of the manifold 136 is input the showerhead 108 (e.g., a multi-injector, multi-zone showerhead as described below in more detail). While the manifolds 128 and 136 are shown, a single manifold can be used.

In some examples, a temperature of the substrate support 116 may be controlled using resistive heaters 144. In some examples, the resistive heaters 144 are arranged in different heating zones to separately control temperatures in respective heating zones of the substrate support 116. The substrate support 116 may comprise coolant channels 146. Cooling fluid is supplied to the coolant channels 146 from a fluid storage 148 and a pump 150. Pressure sensors 152, 154 may be arranged in the manifold 128 or the manifold 136, respectively, to measure pressure. A valve 156 and a pump 158 may be used to evacuate (i.e., purge) reactants from the processing chamber 104 and/or to control pressure within the processing chamber 104.

A controller 160 comprises a dose controller 162 that controls dosing provided by the showerhead 108. The controller 160 also controls gas delivery from the gas delivery system 120. The controller 160 controls pressure in the processing chamber and/or purging of reactants using the valve 156 and the pump 158. The controller 160 controls the temperature of the substrate support 116 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 104 as deposition processes. Accordingly, the substrate processing system 100 may comprise an RF generating system 164 configured to generate and provide RF power (e.g., as a voltage source, current source, etc.) to one of a lower electrode (e.g., a baseplate of the substrate support 116, as shown) and an upper electrode (e.g., the showerhead 108). The other one of the lower electrode and the upper electrode may be DC grounded, AC grounded or floating.

For example only, the RF generating system 164 may comprise an RF generator 166 configured to generate the RF voltage that is fed by a matching and distribution network 168 to generate plasma within the processing chamber 104 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only, transformer coupled plasma (TCP) systems, CCP cathode systems, remote microwave plasma generation and delivery systems, etc.

The substrate support 116 comprises a cover ring 170. In some examples, an inner edge of the cover ring 170 overlaps an outer edge of the substrate 112. In some examples, the substrate support 116 is lowered for transfer of the substrate 112 into the processing chamber 104. For example, the substrate 112 is transferred onto lift pins (not shown in FIG. 1) that are exposed when the substrate support 116 is lowered. When the substrate support 116 is lowered, the cover ring 170 may be supported on a structure such as a pumping ring as described below in more detail. The substrate support 116 is then raised to engage the substrate 112 and the cover ring 170.

In some examples, the processing chamber 104 is purged through one or more purge ports 180 (e.g., bottom purge ports) located in a bottom surface of the processing chamber 104. For example, the valve 156 and the pump 158 are controlled to selectively purge reactants downward through the processing chamber 104 and out of the purge port 180. The processing chamber 104 and the substrate support 116 according to the present disclosure are configured to increase symmetry of a purge volume defined within the processing chamber 104 and facilitate a uniform, annular distribution of pumping flow as described below in more detail.

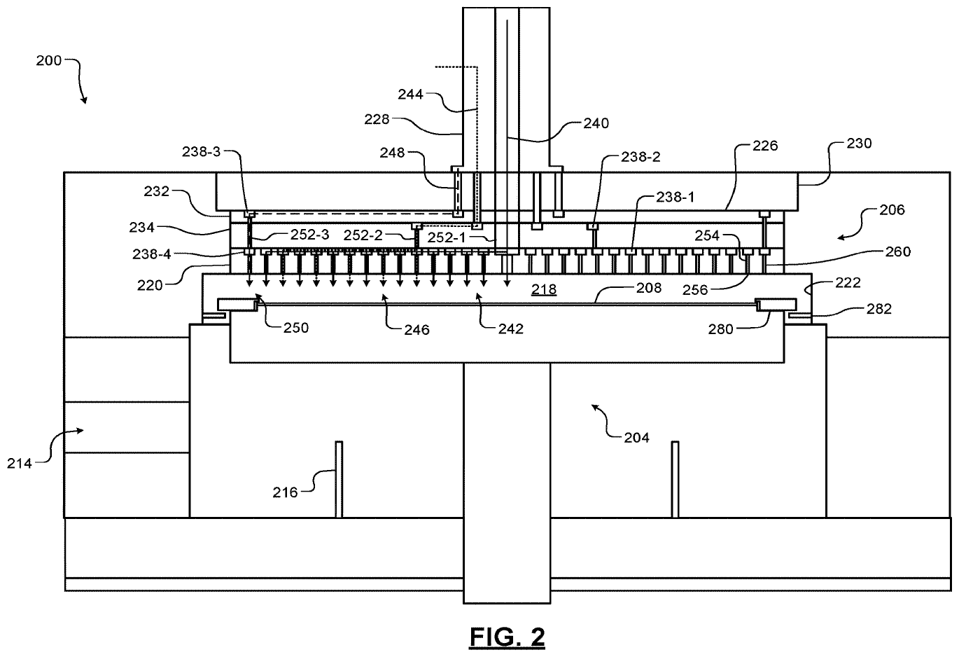

FIG. 2 shows an example processing chamber 200 comprising a substrate support (e.g., a pedestal) 204 according to the present disclosure. In some examples, the processing chamber 200 is comprised of a multi-part assembly. In an example, the processing chamber 200 corresponds to a station of a single station module. The processing chamber 200 is configured to supply reactants from a showerhead 206 to perform a bulk deposition step on a substrate 208 subsequent to a nucleation step performed in a different processing chamber. For example, subsequent to a nucleation step, the substrate 208 is transferred to a substrate support (e.g., a pedestal) 212 arranged within the processing chamber 200.

In one example, the substrate 208 is transferred through a slot or other opening 214 in a sidewall of the processing chamber 200 when the pedestal 204 is in a lowered position. When the pedestal 204 is in the lowered position, lift pins 216 extend above an upper surface of the pedestal 204 and the substrate 208 is placed onto the lift pins 216 (e.g., using a transfer robot). The pedestal 204 is then raised to lift and support the substate 208 in a raised position as shown in FIG. 2. In other words, the lift pins 216 are static (i.e., fixed) lift pins that do not raise and lower. Instead, the pedestal 204 is raised and lowered for placement of the substrate 208.

Each of the processing chamber 200, the showerhead 206, and the pedestal 204 is configured to minimize azimuthal non-symmetries in a deposition zone 218 defined between the showerhead 206 and the pedestal 204. For example, the deposition zone 218 is a symmetrically annular volume defined between a lower, substrate-facing faceplate 220 of the showerhead 206, an annular inner surface 222 of the processing chamber 200, and the pedestal 204. Further, a gap between the faceplate 220 and the pedestal 204 is minimized to maintain uniformity of process gas flow and distribution within the deposition zone 218.

The showerhead 206 is comprised of a base or head portion 226 and a stem portion 228. The stem portion 228 extends through an upper wall (e.g., a lid 230) of the processing chamber 200 to connect to the head portion 226. For example, the head portion 226 comprises the faceplate 220, a backplate 232, and a middle plate 234 disposed between the faceplate 220 and the backplate 232. In this example, the faceplate 220 functions as an upper surface of the processing chamber 200.

The faceplate 220, the backplate 232, and the middle plate 234 define at least three flow paths and respective plenums 238 within the head portion 226 to provide radial tunability and process configurability. For example, one or more plenums 238-1 are defined in an upper surface of the faceplate 220, a plenum 238-2 is defined in an upper surface of the middle plate 234, a plenum 238-3 is defined in an upper surface of the backplate 232, and a plenum 238-4 is defined in the faceplate 220 radially outside of the plenum 238-1. The plenums 238-1, 238-2, 238-3, and 238-4 are referred to collectively as plenums 238.

As shown, a first flow path (shown as solid lines/arrows) 240 supplies gases through the stem 228 and into a corresponding plenum defined in a center zone 242 of the faceplate 220. A second flow path (shown as dotted lines/arrows) 244 supplies gases through the stem 228 and into a corresponding plenum defined in a radial or middle zone 246 of the faceplate 220. A third flow path (shown as dashed lines/arrows) 248 supplies gases through the stem 228 and into a corresponding plenum defined in an outer or edge zone 250 of the faceplate 220. For example only, the first flow path 240 is routed through the stem 228 to supply gases to the center zone 242 via a center inlet 252-1, the second flow path 244 is routed through the backplate 232 and the middle plate 234 to supply gases to the middle zone 246 through a middle inlet 252-2, and the third flow path 248 is routed through the backplate 232 and the middle plate 234 to supply gases to the edge zone 250 through an edge inlet 252-3.

The faceplate 220 includes a plurality of holes 254 extending from the plenums 238 to the deposition zone 218 within the processing chamber 200. For example, gases in the first flow path 240 flow through holes 254 in the center zone 242, gases in the second flow path 244 flow through holes 254 in the middle zone 246, and gases in the third flow path 248 flow through holes 254 in the edge zone 250.

Gases supplied to the center zone 242, the middle zone 246, and the edge zone 250 can be independently controlled to either add or delete specific reactants (i.e., gases) supplied to corresponding regions of the substrate 208. For example, a gas mixture supplied to the deposition zone 218 to perform bulk deposition may include various reactive and non-reactive gases, such as argon (Ar), molecular hydrogen (H₂), tungsten hexafluoride (WF₆), molecular nitrogen (N₂), etc. Other gases and gas mixtures may be supplied in other examples, such as diborane (C₂H₆), silane (SiH₄), etc. Amounts of each of the gases supplied to the respective zones 242, 246, 250 can be controlled (e.g., using separately controllable components of a gas control system, such as the gas control system 120) to tune deposition rates and film properties in the different regions of the substrate 208. In other words, amounts of each gas supplied to each of the zones can be independently controlled.

As shown in FIG. 2, gases provided to the edge zone 250 via the third flow path 248 are provided only to outermost holes 260 in the faceplate 220. In other words, the third flow path 248 does not supply gases to the center zone 242 and the middle zone 246. For example, the holes 260 are in fluid communication with the plenum 238-3 and the plenum 238-4 defined in the edge zone 250 of the faceplate 220 but are not in fluid communication with the plenum 238-1 defined in the center zone 242 and the middle zone 246. As an example, the plenum 238-4 in the edge zone 250 is separated from the plenum 238-1 in the center zone 242 and the middle zone 246.

Conversely, the plenum 238-1 may correspond to a single plenum defined in both the center zone 242 and the middle zone 246. Accordingly, gases supplied via both the first flow path 240 and the second flow path 244 are supplied to the same plenum 238-1. The gases supplied via the first flow path 240 and the second flow path 244 are blended within the plenum 238-1 and flow through the holes 254.

As shown, the processing chamber 200 is an assembly comprised of a first section (e.g., an upper section) 264, a second section (e.g., a lower section) 268, and a third section (e.g., a bottom plate) 272. For example, the first section 264, the second section 268, and the third section 272 are separately-machined aluminum sections that are brazed together to form the processing chamber 200. The processing chamber 200 may include a fourth section (e.g., a top plate or section) 276 configured to engage with the showerhead 206 and the lid 230 and define the deposition zone 218.

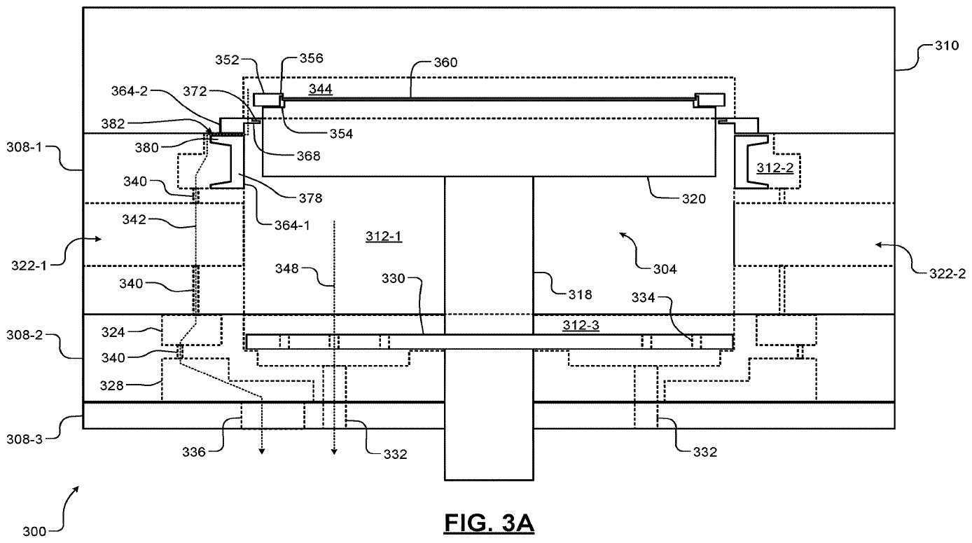

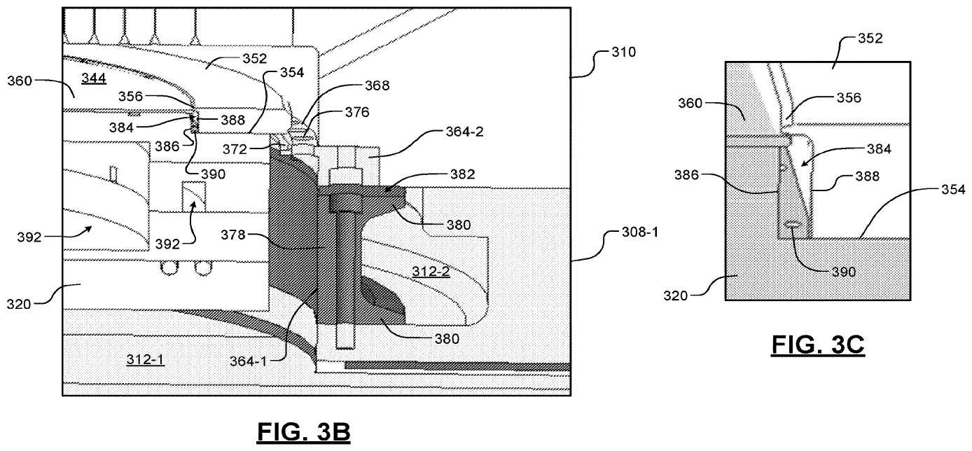

The pedestal 204 according to the present disclosure is configured to support a cover ring 280. The cover ring 280 includes an inner edge or lip that extends over and overlaps/covers an outer edge of the substrate 208. In this manner, the cover ring 280 reduces deposition on the outer edge of the substrate 208. When the pedestal 204 is lowered, the cover ring 280 is supported on a ledge 282, such as an inner edge of an upper pumping ring (not shown in FIG. 2) as described below in FIG. 3A in more detail.

FIG. 3A shows a processing chamber assembly 300 including a pedestal or pedestal assembly 304 according to the present disclosure. In some examples, the processing chamber assembly 300 is comprised of multiple sections, such as a first section 308-1, a second section 308-2, and a third section 308-3 (referred to collectively as the sections 308) according to the present disclosure in more detail. For simplicity of illustration, some details shown in FIG. 2 (e.g., the showerhead 206, the lift pins 216, etc.) are omitted in FIG. 3A. Various manifolds, plenums or interior volumes, and channels defined within the sections 308 are shown as dashed lines. Although shown as three sections (e.g., separately-machined sections that are brazed together), in other examples the assembly 300 may be comprised of fewer or more than three sections and/or formed by different manufacturing methods (e.g., additive manufacturing). A fourth section 310 or top plate (e.g., corresponding to the fourth section 276) may be disposed on the first section 308-1.

The first section 308-1 defines a generally annular plenum or volume including a middle portion 312-1 and an upper portion 312-2 (referred to collectively as, along with a lower portion 312-3, a first volume 312) around the pedestal assembly 304. For example, the middle portion 312-1 surrounds a stem portion 318 of the pedestal assembly 304 below a baseplate portion 320 of the pedestal assembly 304. A diameter of the middle portion 312-1 is generally the same as (or, as shown, slightly greater than) a diameter of the baseplate portion 320. The upper portion 312-2 surrounds the baseplate portion 320. The upper portion 312-2 may have a stepped configuration. In other words, as shown, an outer diameter of the upper portion 312-2 steps radially outward relative to the baseplate portion 320 one or more times. The upper portion 312-2 functions as a first manifold or a first level of manifolding.

The first section 308-1 may include one or more slots 322-1 and 322-2 (referred to collectively as slots 322) providing access to the first volume 312. For example, the slot 322-1 provides access for a substrate to be transferred onto the pedestal assembly 304 as described above. Conversely, the slot 322-2 may function as a viewport to allow visual access to the first volume 312, the pedestal assembly 304, etc.

The second section 308-2 defines a plurality of plenums or volumes including the lower portion 312-3 of the first volume 312, an annular second volume 324, and an annular third volume 328. The lower portion 312-3 and the second volume 324 are defined in an upper surface of the second section 308-2. For example, the lower portion 312-3 is contiguous with the middle portion 312-1 and surrounds the stem portion 318. The second volume 324 is located radially outside of the lower portion 312-3. The second volume 324 functions as a second manifold or second level of manifolding. Conversely, the third volume 328 is defined in a lower surface of the second section 308-2. For example, the third volume 328 has a generally “L” shaped cross-section. The third volume 328 functions as a third manifold or third level of manifolding.

In some examples, a purge plate 330 (e.g., an annular or disc-shaped plate) is disposed in the lower portion 312-3 around the stem portion 318. The purge plate 330 separates the first volume 312 from bottom purge ports 332 extending through the second section 308-2 and the third section 308-3. The purge plate 330 includes a plurality of holes or annular slots 334. Conversely, the third volume 328 is in fluid communication with a main pumping port 336 extending through the third section 308-3.

The upper portion 312-2 of the first volume 312, the second volume 324, and the third volume 328 correspond to first, second, and third levels of manifolding, respectively, to provide internal pumping passages through the first, second, and third sections 304 of the assembly 300. Various channels 340 extend between and fluidly couple the upper portion 312-2 and the second volume 324, the second volume 324 and the third volume 328, etc. The channels 340 may be arranged in a circular pattern. For example, the channels 340 include a plurality of holes formed in the first section 308-1 and the second section 308-2.

The upper portion 312-2 of the first volume 312, the second volume 324, the third volume 328, and the second channels 340 define internal pumping passages that provide a first flow path 342 for reactants to be evacuated from a deposition volume 344 above the pedestal assembly 304 to the main pumping port 336. For example, as shown, the first flow path 342 is located radially outside of the lower portion 312-1 of the first volume 312 and the baseplate portion 320 of the pedestal assembly 304. The components defining the first flow path 342 are configured to improve pumping uniformity and symmetry to reduce backside deposition on the pedestal assembly 304. Conversely, the bottom purge ports 332 optionally provide additional pumping/purge flow out of the first volume 312 via additional flow paths 348 out of the first volume 312.

The pedestal assembly 304 according to the present disclosure supports a cover ring 352. For example, an upper surface of the baseplate portion 320 has an outward step 354 configured to support the cover ring 352. The cover ring 352 includes an inner lip or edge 356 that extends over and overlaps/covers an outer edge of a substrate 360 disposed on the pedestal assembly 304. The inner edge 356 of the cover ring 352 reduces deposition on the outer edge of the substrate 360.

The pedestal assembly 304 includes a lower pumping ring 364-1 and an upper pumping ring 364-2 (referred to collectively as pumping ring assembly or pumping rings 364) disposed around an outer perimeter of the baseplate portion 320. For example, the pumping rings 364 are annular. The pumping rings 364 separate the upper portion 312-2 from the middle portion 312-1 of the first volume 312. The pumping rings 364 are configured to regulate flow of reactants from the deposition volume 344 and into the upper portion 312-2 via the first flow path 342. Accordingly, when the main pumping port 336 is operated to evacuate the deposition volume 344 as described above, reactants are drawn into the upper portion 312-2 through the pumping rings 364 and then through the second volume 324 and the third volume 328.

As shown in FIG. 3A and in more detail in FIG. 3B, the upper pumping ring 364-2 is mounted to a bottom surface of the top plate 310 (e.g., between the top plate 310 and the first section 308-1). For example, the upper pumping ring 364-2 is attached to the top plate 310 via fasteners, such as screws. The upper pumping ring 364-2 includes a ledge (e.g., a step or projection that extends radially inward) 368 disposed below an outer edge of the cover ring 352. Accordingly, when the pedestal assembly 304 is lowered to facilitate transfer of the substrate 360 to and from the baseplate portion 320, the cover ring 352 is supported on the ledge 368. For example, the ledge 368 may define an annular inner recess 372 configured to support the cover ring 352.

As shown in FIG. 3B, the ledge 368 includes a plurality of openings or holes 376. The holes 376 are arranged circumferentially around the ledge 368. The holes 376 are configured to allow reactants to flow through the upper pumping ring 364-2, from above the upper pumping ring 364-2 (i.e., from the deposition volume 344) to below the upper pumping ring 364 (i.e., to the first volume 312).

Conversely, the lower pumping ring 364-1 is mounted to an upper surface of the first section 308-1 within the upper portion 312-2 of the first volume 312. For example, the lower pumping ring 364-1 is generally “C”-shaped and includes a radially inner vertical portion (e.g., an annular body portion) 378 and horizontal legs 380 extending radially outward from upper and lower ends of the body portion 378. The upper portion 312-2 of the first volume 312 is defined between outer surfaces of the lower pumping ring 364-1 and inner surfaces of the first section 308-1.

A flow channel or gap 382 (e.g., a horizontal gap) is defined between an upper surface of the lower pumping ring 364-1 and a lower surface of the upper pumping ring 364-2. The gap 382 allows reactants to flow radially outward between the pumping rings 364 and into the upper portion 312-2.

Referring now to FIG. 3C with continued reference to FIGS. 3A and 3B, an annular backside purge volume or gap 384 is defined between an outer surface 386 of the baseplate portion 320 and an inner surface 388 of the cover ring 352. A plurality of holes 390 are circumferentially disposed in a portion of the outward step 354 within the purge volume 384. The holes 390 are located within the backside purge volume 384 below the outer edge of the substrate 360 and the inner edge 356 of the cover ring 352.

A gas (e.g., a purge or inert gas, such as argon) is supplied to the backside purge volume 384 via the holes 390. For example, the gas may be supplied to one or more plenums 392 defined within the baseplate portion 320 (as shown in FIG. 3B), and from the plenums 392, through the holes 390, and into the backside purge volume 384. The gas supplied to the backside purge volume 384 in this manner pressurizes the backside purge volume 384 and prevents reactants from flowing between the outer edge of the substrate 360 and the cover ring 352. Accordingly, backside deposition is reduced.

Further, frontside deposition (i.e., on an upper surface) at an outermost edge (e.g., an outermost 1 mm, a bevel region, etc.) of the substrate 360 is reduced or eliminated. Typically, substrate handling components contact the outermost edge of the substrate 360 during transfer. Contact between the substrate handling components and deposition material on the edge of the substrate 360 may cause particles of the deposition material to shed. Accordingly, supplying the purge gas to the backside purge volume 384 prevents deposition on the outermost edge and/or bevel of the substrate 360 to reduce potential particle generation.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform, or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal assembly for a substrate processing system configured to perform bulk deposition on a substrate, wherein the pedestal assembly is configured to be raised and lowered, the pedestal assembly comprising:
a stem portion;
a baseplate portion disposed on the stem portion, wherein the baseplate portion is configured to support the substrate; and
a pumping ring assembly disposed around the baseplate portion, wherein the pumping ring assembly includes (i) a lower pumping ring and (ii) an upper pumping ring disposed above the lower pumping ring, and wherein the pumping ring assembly is configured to define an annular volume radially outside of the pumping ring assembly such that the pumping ring assembly separates the annular volume from a volume defined below the baseplate portion of the pedestal assembly.

2. The pedestal assembly of claim 1, further comprising a cover ring configured to be supported on the baseplate portion when the pedestal assembly is in a raised position, the cover ring including an inner edge configured to overlap and extend above an outer edge of the substrate when the substrate is arranged on the baseplate portion.

3. The pedestal assembly of claim 2, wherein the upper pumping ring is configured to support the cover ring when the pedestal assembly is in a lowered position.

4. The pedestal assembly of claim 3, wherein the upper pumping ring includes a ledge extending radially inward, and wherein the cover ring is supported on the ledge.

5. The pedestal assembly of claim 4, wherein the upper pumping ring includes an inner annular recess defined in the ledge, and wherein the cover ring is supported in the inner annular recess.

6. The pedestal assembly of claim 3, further comprising a backside purge volume defined between the baseplate portion and the cover ring below the outer edge of the substrate and the inner edge of the cover ring.

7. The pedestal assembly of claim 6, further comprising a plurality of holes defined in an upper surface of the baseplate portion within the backside purge volume, wherein the plurality of holes is configured to supply purge gas to the backside purge volume.

8. The pedestal assembly of claim 1, further comprising a plurality of holes defined in the upper pumping ring, wherein the plurality of holes is configured to allow reactants to flow from a deposition volume above the baseplate portion into the volume defined below the baseplate portion.

9. The pedestal assembly of claim 8, further comprising a gap defined between the upper pumping ring and the lower pumping ring, wherein the gap is configured to allow reactants to flow radially outward from below the lower pumping ring into the annular volume radially outside of the lower pumping ring assembly.

10. The pedestal assembly of claim 9, wherein the lower pumping ring is generally “C”-shaped.

11. The pedestal assembly of claim 10, wherein the lower pumping ring includes an annular body portion and legs extending radially outward from upper and lower ends of the annular body portion.

12. A processing chamber assembly comprising the pedestal assembly of claim 1.

13. The processing chamber assembly of claim 12, further comprising a first section that defines the volume below the baseplate portion, wherein the annular volume radially outside of the pumping ring assembly is defined between inner surfaces of the first section and outer surfaces of the lower pumping ring.

14. The processing chamber assembly of claim 13, further comprising a top plate disposed on the first section, wherein the top plate defines a deposition volume above the baseplate portion.

15. The processing chamber assembly of claim 14, wherein the lower pumping ring is mounted to a lower surface of the top plate.

16. A substrate support for a substrate processing system configured to perform bulk deposition on a substrate, the substrate support comprising:
a baseplate portion, wherein the baseplate portion is configured to support the substrate; and
a pumping ring assembly disposed around the baseplate portion, wherein the pumping ring assembly is configured to define an annular volume radially outside of the pumping ring assembly such that the pumping ring assembly separates the annular volume from a volume defined below the baseplate portion of the substrate support.

17. The substrate support of claim 16, wherein the pumping ring assembly includes (i) a lower pumping ring and (ii) an upper pumping ring disposed above the lower pumping ring.

18. The substrate support of claim 17, wherein the baseplate portion includes an outward step, the substrate support further comprising a cover ring configured to be supported on the outward step.

19. The substrate support of claim 18, wherein the substrate support is configured to be raised and lowered, and wherein the cover ring is configured to be (i) supported on the outward step when the substrate support is in a raised position and (ii) supported on the upper pumping ring when the substrate support is in a lowered position.

20. The substrate support of claim 17, wherein the upper pumping ring includes a plurality of holes configured to allow reactants to flow from a deposition volume above the baseplate portion into the volume defined below the baseplate portion, and wherein a gap defined between the lower pumping ring and the upper pumping ring is configured to allow reactants to flow from below the upper pumping ring into the annular volume radially outside of the pumping ring assembly.
